(19) United States
(12) Patent Application Publication
(10) Pub. No.: US 2025/0165677 A1
(43) Pub. Date: May 22, 2025

(54) DEVICES, SYSTEMS, AND METHODS RECURRENT GRAPH NEURAL NETWORKS IN ACCELERATED, VARIABLE LOAD FINITE ELEMENT ANALYSIS

(71) Applicant: VOLKSWAGEN AKTIENGESELLSCHAFT, Wolfsburg (DE)

(72) Inventors: Megan HARDY, San Francisco, CA (US); Brett DUFFORD, San Mateo, CA (US); Gianina Alina NEGOITA, San Leandro, CA (US); Wesley TESKEY, Foster City, CA (US); Lars GREVE, Rühn (DE); Bram Pieter VAN DE WEG, Wolfsburg (DE); Simon THEL, Braunschweig (DE)

(21) Appl. No.: 18/511,611

(22) Filed: Nov. 16, 2023

(51) Int. Cl. G06F 30/27; G06F 30/12; G06F 30/15; G06F 30/23

(52) U.S. Cl. CPC G06F 30/27; G06F 30/12; G06F 30/15; G06F 30/23

(57) ABSTRACT

Devices, systems, and methods accelerated, variable load finite element analysis for vehicle design can provide a graphical representation of a finite element mesh and enter the graphical representation as an input to a recurrent neural network (RNN). Such solutions can develop a time series mesh (TSM) as an output from the RNN. Design of a component of the vehicle can be adapted based on the output.

The present disclosure relates to devices, systems, and methodologies for vehicle component designs using neural networks for dynamic analysis. More particularly, the present disclosure relates to devices, systems, and methodologies for rapid, variable loading concerns internal and external influences, and even more particularly rapid, variable load FEA of vehicular components.

### BACKGROUND

In engineering design, such as for vehicular components for cars, trucks, and buses, finite element analysis (FEA) can provide important consideration and/or input to design aspects. Whether in collision analysis, fatigue analysis, electromagnetic shielding consideration, or otherwise, FEA can allow designers to appreciate advantages and/or disadvantages of geometries, materials, and/or other component aspects. Traditional FEA can require intensive simulation applying considerable computational resources, and can take valuable time to occur. Reducing the burdens of FEA can improve design cycles and/or overall components.

### SUMMARY

According to an aspect within the present disclosure, a method of accelerated, variable load finite element analysis for vehicle design may include providing a graphical representation of a finite element mesh; entering the graphical representation as an input to a recurrent neural network (RNN); developing a time series mesh (TSM) as an output from the RNN; and adapting a design of a component of the vehicle based on the output. In some embodiments, the method may further include repeating providing a graphical representation of a finite element mesh based on the adapted design of the component of the vehicle.

In some embodiments, the method may further include repeating entering the graphical representation based on the adapted design as an input to the RNN. The method may further include repeating developing a TSM as an output from the RNN based on the input graphical representation based on the adapted design as a new output. The method may further include finalizing the design of the component of the vehicle based on the new output from the RNN.

In some embodiments, providing the graphical representation may include providing the finite element mesh. Providing the graphical representation may include generating the graphical representation based on the finite element mesh. Entering the graphical representation as an input to the recurrent neural network may include encoding and decoding.

In some embodiments, entering the graphical representation as an input to the recurrent neural network may include operation of a Long Short Term Memory (LSTM) module. Operation of the LSTM module may be conducted between encoding and decoding. Operation of the LSTM module may be conducted on the graphical representation as a cohesive input to the LSTM module. Encoding may include pooling and decoding includes unpooling. In some embodiments, pooling and unpooling may each include convolution.

In some embodiments, the method may further include determining a pooling depth, and pooling and unpooling may be conducted according to the pooling depth. In some embodiments, developing a TSM may include generating as the output, a graphical representation of the finite element mesh having time series, having undergone pooling, unpooling, and operation of the LSTM module.

In some embodiments, adapting the design of the component of the vehicle based on the output may include adapting the design of the component on which the finite element mesh is based. Adapting the design may include modifying at least one physical dimension of the design of the component.

According to another aspect of the present disclosure, a system for vehicular component design may include a control system having at least one processor configured for executing instructions stored on memory to conduct operations including: providing a graphical representation of a finite element mesh; entering the graphical representation as an input to a recurrent neural network (RNN); developing a time series mesh (TSM) as an output from the RNN; and providing indication of adaption for design of the vehicular component based on the TSM. The operations may further include repeating at least one of: providing a graphical representation of a finite element mesh based on the adapted design of the component of the vehicle; entering the graphical representation based on the adapted design as an input to the RNN; and developing a TSM as an output from the RNN based on the input graphical representation based on the adapted design as a new output.

According to another aspect of the present disclosure, a method of accelerated, variable load finite element analysis may include providing a graphical representation of a finite element mesh; entering the graphical representation as an input to a recurrent neural network (RNN); and developing a time series mesh (TSM) as an output from the RNN. The method may include repeating at least one of: providing a graphical representation of a finite element mesh based on the adapted design of the component of the vehicle; entering the graphical representation based on the adapted design as an input to the RNN; and developing a TSM as an output from the RNN.

Additional features of the present disclosure will become apparent to those skilled in the art upon consideration of illustrative embodiments exemplifying the best mode of carrying out the disclosure as presently perceived.

### BRIEF DESCRIPTION OF THE DRAWINGS

The detailed description particularly refers to the accompanying figures in which:

FIG. 1 is diagrammatic flow illustration indicating a process including analysis and/or design that applies accelerated, variable load FEA, according to illustrative embodiments within the present disclosure;

FIG. 2 is diagrammatic view of applying accelerated, variable load FEA, indicating graphical mesh representation as input to a recurrent neural network, according to illustrative embodiments within the present disclosure;

FIG. 3 is another diagrammatic view of applying accelerated, variable load FEA, indicating graphical mesh representation as input to a recurrent neural network, according to illustrative embodiments within the present disclosure; and

FIG. 4 is a diagrammatic view of applying accelerated, variable load FEA, indicating graphical mesh representation as input to a recurrent neural network, including graph pooling and unpooling.

### DETAILED DESCRIPTION

Ever-evolving design of components, for example, vehicular components can benefit from rigorous testing/analysis. For example, whether in load testing, collision simulation, stress/strain/fatigue analysis, electromagnetic shielding consideration, heat resistance analysis, vibration effects, fluid flows, chemical/UV exposure analysis, or otherwise, thorough development in consideration of these aspects can yield design improvements to performance, cost, and/or failure rates. Finite element analysis (FEA) can allow evaluation of advantages and/or disadvantages of geometries, materials, coatings, collective operations, and/or other component aspects.

Traditional FEA simulations applying traditional finite element methods can require considerable time and/or computing resources to provide results. Near immediate feedback concerning designs can be challenging to obtain, extending the design process and/or occupying computing resources. Moreover, some traditional FEA approaches can be limited in static loading and/or output to individual state, as a final state, which can prevent consideration of dynamic loadings.

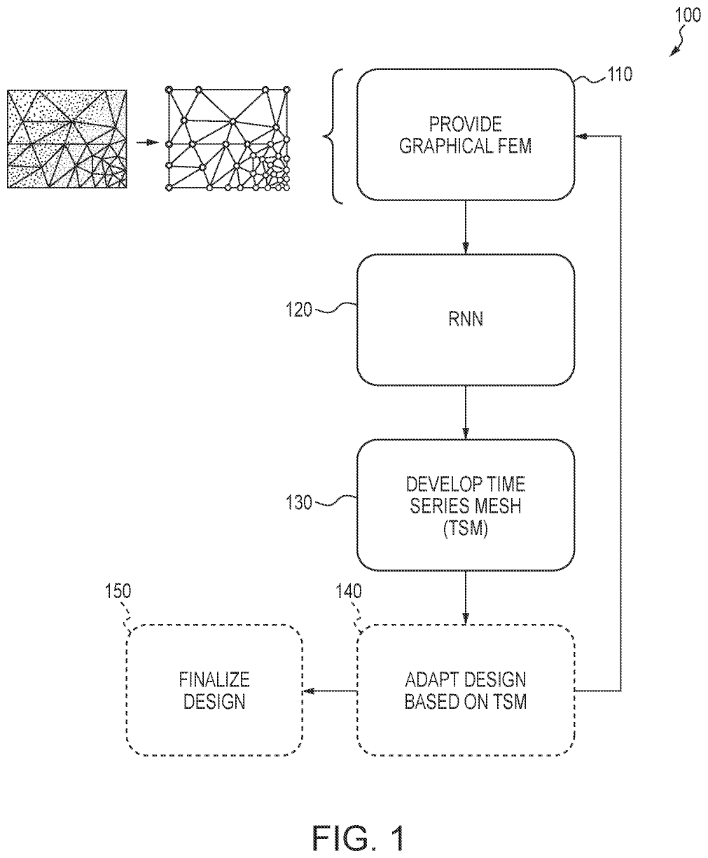

Referring to FIG. 1, a flow diagram 100 is shown indicating a component design approach according to illustrative embodiments concerning boxes 110-130, and optionally boxes 140, 150. In box 110, a graphical representation of a finite element mesh of a component is provided.

In the illustrative embodiment, the graphical representation is generated from the traditional finite element mesh where the traditional mesh corresponds to a current component design. Intersections of finite elements of the traditional finite element mesh are represented as nodes in the graph. Edges of finite elements of the traditional finite element mesh are represented by connection between nodes.

Features of each graphical node are illustratively extrapolated from their traditional finite element nodes and/or adjacent traditional finite elements. In some embodiments, other suitable techniques for generating the graphical representation may be applied, including for example, directly generating a graphical mesh representing traditional finite element mesh.

In box 120, the graphical representation is entered as an input to a neural network. The neural network is formed as a recurrent neural network (RNN), applying recurrent message passing as discussed in additional detail herein. In the illustrative embodiment, the RNN considers the entire graphical representation at once, rather than an element-by-element.

In box 130, a time series mesh (TSM) is developed as an output from the RNN. The TSM allows consideration of time-dependent characteristics of the mesh which can permit dynamic load consideration as discussed in additional detail herein. In the illustrative embodiment, the TSM is formed as a graphical representation having the same general structure as that of the input graphical representation, modified according to the RNN.

In box 140, the component design is optionally adapted based on the TSM. For example, in the instance of a collision analysis, areas observed to benefit from increased or decreased material dimensions can be adjusted, geometries can be altered, and/or other structural parameters adjusted, according to the TSM to improve the component design.

In some embodiments, the adapted design resultant from box 140 may be applied in boxes 110-130 to reiterate the design. A graphical representation corresponding to the adapted design is provided, entered as input to the RNN, and an adapted TSM developed. Component design may be adapted based on the adapted TSM. Further iterations may be undertaken.

In box 150, component design may be optionally finalized. In the illustrative embodiment, design finalization is conducted upon achieving threshold values for the interested aspect of design. Continuing the example of collision analysis, upon remaining below maximum acceptable threshold stress levels for all portions of the component, design finalization can be undertaken. For example, for a given design and/or material, a threshold of stress/strain may be applied to require that the component remain within the elastic region such as less than 5% from the plastic region as an acceptable threshold, although in some embodiments other suitable thresholds may be applied.

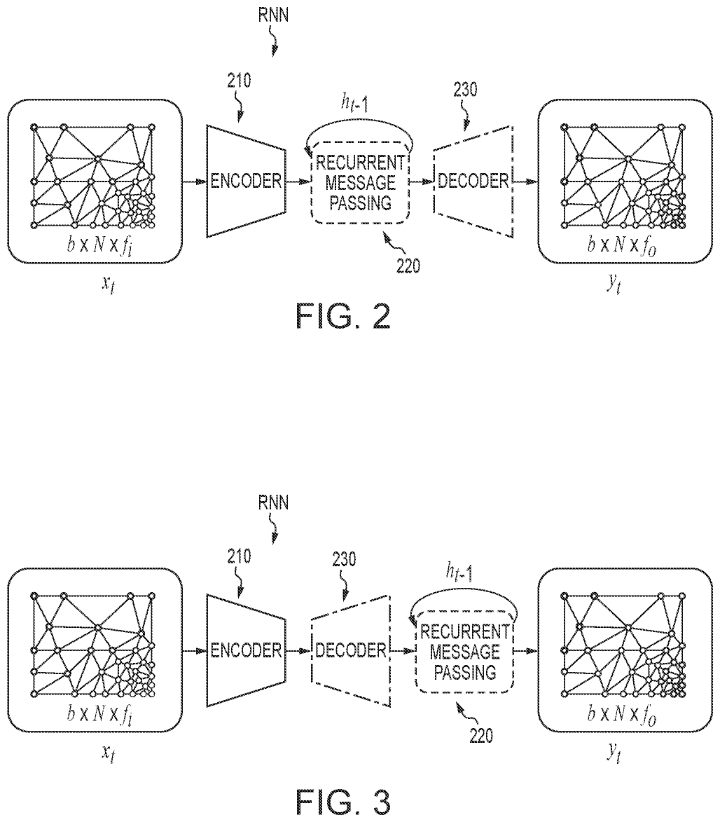

Referring now to the illustrative embodiment as indicated in FIG. 2, the graphical representation is shown as xₜ, indicating the representation of the traditional finite element mesh at time t. The graphical representation is entered as input and received by the RNN. The TSM is generated as an output from the RNN as shown as yₜ.

The graphical representation xₜ is illustratively provided in the form b×N×fᵢ, where b defines the batch size, N defines the number of nodes, and fᵢ defines the number of input features of the graphical representation of the mesh. In the illustrative embodiment, input features fᵢ can include node-level and/or environmental-level features.

Continuing the collision analysis example, node-level features include thickness and/or type of material of the component at the area corresponding with the node. Environmental-level features illustratively include velocity, general type of impact, temperature, and/or road conditions. Of course, in some embodiments, additional node-level and/or environmental-level features may be included according to the desired scenario.

Similarly, the TSM yₜ is illustratively provided in the form b×N×fₒ, where b defines the batch size, N defines the number of nodes, and fₒ defines the number of output features of the TSM (predicted). In the illustrative embodiment, the structure of the TSM graph at output yₜ remains similar to the graphical representation at input xₜ, such that the structure generally remains the same from input to output as a static graph neural network. In the exemplary collision analysis, for example, fₒ is illustratively embodied to be 3-dimensional, where the features of yₜ include the displacement of the nodes in 3D space from their fᵢ origin. such that node-level output features are predicted for each time step, t.

As suggested in FIG. 2, the RNN illustratively includes an encoder module 210, an recurrent module 220, and decoder module 230. In the illustrative embodiment, the recurrent module 220 is arranged between the encorder and decord modules 210, 230, but in some embodiments, the recurrent module 220 may be arranged after the decoder module 230 as suggested in FIG. 3.

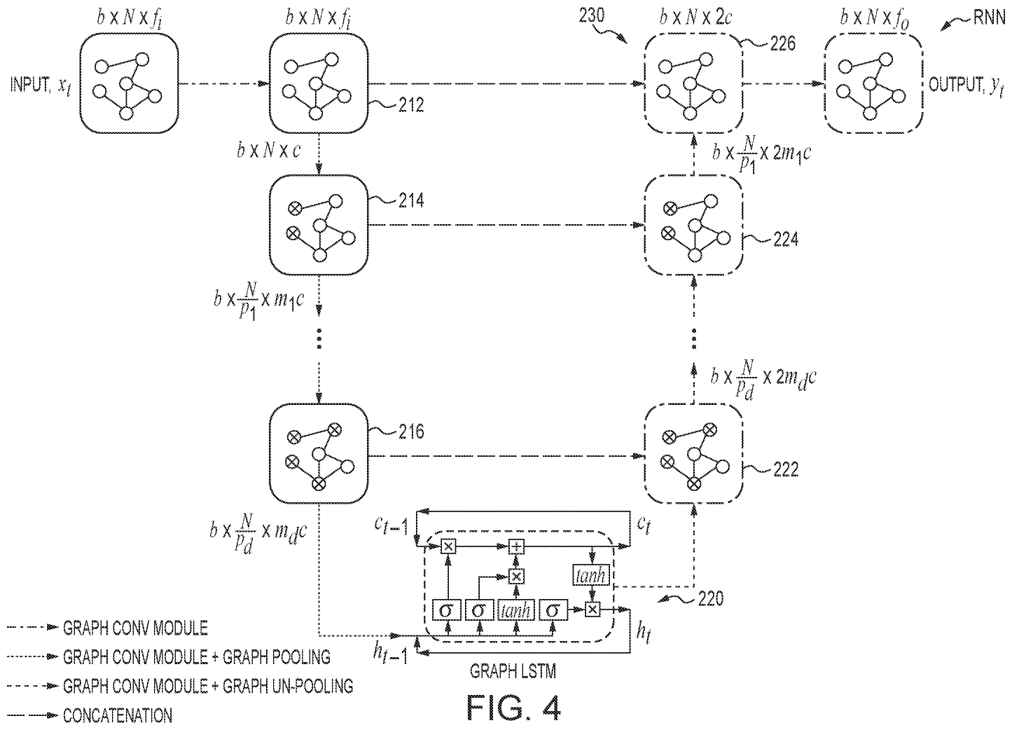

Referring to FIG. 4, the RNN is shown with additional detail illustratively embodied as a U-Net convolutional neural network. The input graphical representation xₜ is entered as input on the left hand side in the orientation of FIG. 4, and illustratively undergoes graph convolution via a graph convulational module of the RNN, as depicted approaching box 212. The boxes 214 and 216 represent first (p₁) and subsequent (p_{d}) levels of graph pooling having depth d corresponding to the levels of pooling values p_{d}, where 0<p_{d}<1. For example, p_{d}=2 for two times downsampling has been applied in certain instances, although other suitable values may be applied. In the illustrative embodiment, the multiplication factors mad are applied to increase the number of channels at deeper levels of the U-Net, where m_{d}≥1. For example, m_{d}=2 can be applied for smaller depth d, and m_{d}=1 can be applied for larger depth d for baseline instances, although other suitable values may be applied. The multiplication factor m_{d} is multiplied by the characteristic factor c, where c represents the number of channels of the network. The characteristic factor c can be ordinarily applied as a factor of 2, for example, 2, 4, or 6, but other suitable values may be applied.

The result from box 216 is entered into the recurrent module 220, illustratively embodied as a Long Short Term Memory (LSTM) module. Namely, the result from box 216 is entered as a hidden state hₜ₋₁ comprising the encoded graphical representation of the previous existing step. An output hₜ of the LSTM module indicates the encoded graphical representation of the current existing step, which can be fed back to the input of the LSTM module. A memory state cₜ (or forget gate) is output from the LSTM module as the current existing step, and can be fed back as input to the LSTM module of the previous existing step cₜ₋₁.

In the illustrative embodiment the LSTM module is arranged to provide conventional long short term memory recurrent message operation including the memory and previous hidden states as disclosed. In some embodiments, other suitable memory techniques may be applied.

At box 222, the encoded graphical representation of the current existing step hₜ output of the LSTM module is unpooled and concatenated with the encoded graph representation of box 216. Similarly, from box 222 the result is unpooled and concatenated with the encoded graph representation of box 214.

The result from box 224 is unpooled and concatenated with the encoded graph representation of box 212. Of course, additional levels of pooling between boxes 214, 224 and boxes 216, 222 would apply in similar manner as applicable. The encoded graph representation of box 226 undergoes final graph convolution to develop the TSM at output yₜ.

Within the present disclosure, graphical RNN FEA can dramatically reduce the time and/or computational resources for application of finite element methods. Component design can be enhanced in similar manner. For example, in the continuing instance of collision analysis, more rapid analysis having lower computational demands can promote ease and effectiveness in design lifecycle, encouraging high quality design by overcoming constraints.

The present disclosure includes operation of machine learning and/or generative artificial intelligence modules, which can include execution of instructions stored on memory by one or more processors to conduct such operations, and may include communication circuitry to communicate governing and/or facilitating signals to and/or from other devices and/or systems. Examples of suitable processors may include one or more microprocessors, integrated circuits, system-on-a-chips (SoC), among others.

Examples of suitable memory, may include one or more primary storage and/or non-primary storage (e.g., secondary, tertiary, etc. storage); permanent, semi-permanent, and/or temporary storage; and/or memory storage devices including but not limited to hard drives (e.g., magnetic, solid state), optical discs (e.g., CD-ROM, DVD-ROM), RAM (e.g., DRAM, SRAM, DRDRAM), ROM (e.g., PROM, EPROM, EEPROM, Flash EEPROM), volatile, and/or non-volatile memory; among others. Communication circuitry may include components for facilitating processor operations, for example, suitable components may include transmitters, receivers, modulators, demodulators, filters, modems, analog/digital (AD or DA) converters, diodes, switches, operational amplifiers, and/or integrated circuits.

Examples of suitable graph U-Net arrangements and LSTM techniques can be found, respectively, within Gao, Hongyang, and Shuiwang Ji. “Graph u-nets.” international conference on machine learning. PMLR, 2019 and Chen, Jinyin, Xueke Wang, and Xuanheng Xu. “GC-LSTM: Graph convolution embedded LSTM for dynamic network link prediction.” Applied Intelligence (2022), the contents of each of which are hereby incorporated by reference in their entiries.

Although certain embodiments have been described and illustrated in exemplary forms with a certain degree of particularity, it is noted that the description and illustrations have been made by way of example only. Numerous changes in the details of construction, combination, and arrangement of parts and operations may be made. Accordingly, such changes are intended to be included within the scope of the disclosure, the protected scope of which is defined by the claims.

What is claimed is:

1. A method of accelerated, variable load finite element analysis for vehicle design, the method comprising:
providing a graphical representation of a finite element mesh;
entering the graphical representation as an input to a recurrent neural network (RNN);
developing a time series mesh (TSM) as an output from the RNN; and
adapting a design of a component of the vehicle based on the output.

2. The method of claim 1, further comprising repeating providing a graphical representation of a finite element mesh based on the adapted design of the component of the vehicle.

3. The method of claim 2, further comprising repeating entering the graphical representation based on the adapted design as an input to the RNN.

4. The method of claim 3, further comprising repeating developing a TSM as an output from the RNN based on the input graphical representation based on the adapted design as a new output.

5. The method of claim 4, further comprising finalizingxd the design of the component of the vehicle based on the new output from the RNN.

6. The method of claim 1, wherein providing the graphical representation includes providing the finite element mesh and generating the graphical representation based on the finite element mesh.

7. The method of claim 1, wherein entering the graphical representation as an input to the recurrent neural network includes encoding and decoding.

8. The method of claim 7, wherein entering the graphical representation as an input to the recurrent neural network includes operation of a Long Short Term Memory (LSTM) module.

9. The method of claim 8, wherein operation of the LSTM module is conducted between encoding and decoding.

10. The method of claim 8, wherein operation of the LSTM module is conducted on the graphical representation as a cohesive input to the LSTM module.

11. The method of claim 7, wherein encoding includes pooling and decoding includes unpooling.

12. The method of claim 11, wherein pooling and unpooling include convolution.

13. The method of claim 11, further comprising determining a pooling depth, and wherein pooling and unpooling are conducted according to the pooling depth.

14. The method of claim 11, wherein developing a TSM includes generating as the output, a graphical representation of the finite element mesh having time series, having undergone pooling, unpooling, and operation of the LSTM module.

15. The method of claim 1, wherein the adapting the design of the component of the vehicle based on the output includes adapting the design of the component on which the finite element mesh is based.

16. The method of claim 15, wherein adapting the design includes modifying at least one physical dimension of the design of the component.

17. A system for vehicular component design, the system comprising:
a control system including at least one processor configured for executing instructions stored on memory to conduct operations including:
providing a graphical representation of a finite element mesh;
entering the graphical representation as an input to a recurrent neural network (RNN);
developing a time series mesh (TSM) as an output from the RNN; and
providing indication of adaption for design of the vehicular component based on the TSM.

18. The system of claim 17, further comprising
repeating at least one of:
providing a graphical representation of a finite element mesh based on the adapted design of the component of the vehicle; entering the graphical representation based on the adapted design as an input to the RNN; and developing a TSM as an output from the RNN based on the input graphical representation based on the adapted design as a new output.

19. A method of accelerated, variable load finite element analysis, the method comprising:
providing a graphical representation of a finite element mesh;
entering the graphical representation as an input to a recurrent neural network (RNN); and
developing a time series mesh (TSM) as an output from the RNN.

20. The method of claim 19, further comprising
repeating at least one of:
providing a graphical representation of a finite element mesh based on the adapted design of the component of the vehicle; entering the graphical representation based on the adapted design as an input to the RNN; and developing a TSM as an output from the RNN.
